(19) United States
(12) Patent Application Publication
(10) Pub. No.: US 2026/0120788 A1
(43) Pub. Date: Apr. 30, 2026

(54) MEMORY DEVICE AND METHOD FOR OPERATING THE SAME

(71) Applicant: Samsung Electronics Co., Ltd., Suwon-si, Gyeonggi-do (KR)

(72) Inventor: Jong Pil SON, Suwon-si (KR)

(73) Assignee: Samsung Electronics Co., Ltd., Suwon-si, Gyeonggi-do (KR)

(21) Appl. No.: 19/262,441

(22) Filed: Jul. 8, 2025

(30) Foreign Application Priority Data
Oct. 24, 2024 (KR) 10-2024-0146692

(51) Int. Cl. G11C 29/56; G11C 11/4074; G11C 11/4093

(52) U.S. Cl. CPC G11C 29/56016; G11C 11/4074; G11C 11/4093

(57) ABSTRACT

A memory device comprises a plurality of core dies including a first core die including a first through silicon via (TSV) area having a plurality of TSVs, and a first cell area including a first memory cell array to store received data, a TSV transfer circuit to input and output data to and from the first memory cell array, a first power management circuit including a latch circuit and configured to manage power of the first core die, and a core control circuit configured to control the first core die in accordance with at least one control command. The first power management circuit is configured to receive, from the core control circuit, a first control signal associated with reducing power supplied to the first cell area, and reduce at least a portion of the power supplied to the first cell area based on the first control signal.

### CROSS-REFERENCE TO RELATED APPLICATION

This U.S. non-provisional application claims priority under 35 U.S.C. 119 from Korean Patent Application No. 10-2024-0146692 filed on Oct. 24, 2024, in the Korean Intellectual Property Office, the entire contents of which are herein incorporated by reference.

### BACKGROUND

Example embodiments are directed to a memory device and a method for operating the same.

A memory device is manufactured through a semiconductor manufacturing process and then tested by a test equipment at a wafer, die or package level. The test process of the memory device may identify a defective portion of the memory device and/or a defective chip. However, the quantity of test equipment capable of testing the memory device is limited, and a maximum power that may be used per test equipment is limited. As a result, the larger the power consumed to test one memory device is, the time and cost required for the test may be increased. Studies for reducing the time and cost required to test a memory device are currently being conducted.

### SUMMARY

Example embodiments are directed to provide a memory device with a lower or reduced power consumption.

Example embodiments are also directed to a method for operating a memory device that reduces power consumption of the memory device.

According to some example embodiments, a memory device includes a plurality of core dies including a first core die, the first core die including a first through silicon via (TSV) area including a plurality of TSVs passing through the first core die, and a first cell area including, a first memory cell array configured to store received data, a TSV transfer circuit configured to input and output data to and from the first memory cell array, a first power management circuit configured to manage power of the first core die, the first power management circuit including a latch circuit, and a core control circuit configured to control the first core die in accordance with at least one control command. The first power management circuit is configured to receive, from the core control circuit, a first control signal associated with reducing at least a portion of power supplied to the first cell area, and reduce at least a portion of the power supplied to the first cell area based on the first control signal. The latch circuit of the first power management circuit is configured to maintain a state of the first control signal such that the power of the first cell area is at least partially reduced.

According to some example embodiments, a memory device includes a plurality of core dies including a first core die, the first core die including a first through silicon via (TSV) area having a plurality of TSVs passing through the first core die, and a first cell area including a first memory cell array configured to store received data, a first TSV transfer circuit configured to input and output data to and from the first memory cell array, a first power management circuit configured to manage power of the first core die, the first power management circuit including a latch circuit, and a core control circuit configured to control the first core die in accordance with at least one control command including a first control command associated with reducing at least a portion of power of one or more core dies among the plurality of core dies. The core control circuit is configured to receive the first control command associated with reducing the at least a portion of the power of the one or more core dies among the plurality of core dies, and provide, to the first power management circuit, a first control signal associated with reducing the at least the portion of power supplied to the first cell area, in response to receiving the first control command. The first power management circuit is configured to receive the first control signal from the core control circuit, and reduce at least a portion of the power supplied to the first cell area in accordance with the first control signal.

According to some example embodiments, a method for operating a memory device comprising a plurality of core dies comprises receiving, by a power management circuit of a first core die of the plurality of core dies, a first control signal associated with reducing at least a portion of power supplied to the first core die, reducing, by the power management circuit of, at least a portion of the power supplied to a cell area of the first core die based on the first control signal, and maintaining, by the power management circuit, the first control signal in a state that the power of the cell area is at least partially reduced.

According to some example embodiments, a method for operating a memory device comprising a plurality of core dies includes receiving, by a core control circuit of a first core die of the plurality of core dies, a first control command to reduce at least a portion of power of the first core die, providing, by the core control circuit, to a power management circuit of the first core die a first control signal to reduce at least a portion of power supplied to the first core die in response to receiving the first control command, and reducing, by the power management circuit, at least a portion of the power supplied to a cell area of the first core die in accordance with the first control signal. According to some example embodiments, the plurality of core dies further includes a second core die different from the first core die, and the method further comprises reducing, by the first power management circuit, at least a portion of the power supplied to the first cell area in accordance with the first control signal based on the second core die being under a test operation.

According to some example embodiments, a system includes a memory device, and a host communicably coupled to the memory device. The memory device includes a plurality of core dies including a first core die, the first core die including a first through silicon via (TSV) area including a plurality of TSVs passing through the first core die, and a first cell area including, a first memory cell array configured to store received data, a TSV transfer circuit configured to input and output data to and from the first memory cell array, a first power management circuit configured to manage power of the first core die, the first power management circuit including a latch circuit, and a core control circuit configured to control the first core die in accordance with at least one control command. The first power management circuit is configured to receive, from the core control circuit, a first control signal associated with reducing at least a portion of power supplied to the first cell area, and reduce at least a portion of the power supplied to the first cell area based on the first control signal. The latch circuit of the first power management circuit is configured to maintain a state of the first control signal such that the power of the first cell area is at least partially reduced.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

FIGS. 1 and 2 are block diagrams of a memory system according to some example embodiments.

FIG. 3 is a view illustrating the memory device of FIGS. 1 and 2.

FIG. 4 is a block diagram illustrating a memory device of FIGS. 1 and 2.

FIG. 5 is a block diagram illustrating one of a plurality of core dies according to some example embodiments.

FIG. 6 is a flow chart illustrating a method for operating a memory device according to some example embodiments.

FIG. 7 is a circuit diagram illustrating a power management circuit of FIG. 5 according to some example embodiments.

FIG. 8 illustrates a plurality of core dies including a first stack ID of SID0, a second stack ID of SID1, and a third stack ID of SID2, according to some example embodiments.

FIG. 9 is a block diagram illustrating one of a plurality of core dies according to some example embodiments.

FIG. 10 is a view illustrating a semiconductor package including the memory device of FIGS. 1 and 2.

FIG. 11 is a view illustrating an example implementation of a semiconductor package including the memory device of FIG. 10.

FIG. 12 is a view illustrating a semiconductor package including the memory device of FIG. 1.

FIG. 13 is a view illustrating a semiconductor package including the memory device of FIG. 2.

### DETAILED DESCRIPTION OF EXAMPLE EMBODIMENTS

Hereinafter, example embodiments will be described with reference to the accompanying drawings.

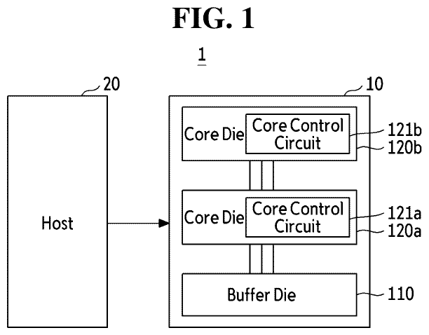

FIG. 1 is a block diagram of a memory system according to some example embodiments. Referring to FIG. 1, a memory system 1 may include a memory device 10 and a host 20. The memory device 10 may be a dynamic random access memory (DRAM) device, but example embodiments are not limited thereto. The memory device 10 may be any one of a plurality of nonvolatile memory devices such as synchronous DRAM (SDRAM), Double Data Rate SDRAM (DDR SDRAM), Low Power Double Data Rate SDRAM (LPDDR SDRAM), Graphics Double Data Rate SDRAM (GDDR SDRAM), DDR2 SDRAM, DDR3 SDRAM, DDR4 SDRAM, DDR5 SDRAM, Wide I/O DRAM, High Bandwidth Memory (HBM) and Hybrid Memory Cube (HMC). According to some example embodiments, the memory device 10 may be any one of a plurality of memory devices mounted on a memory module. The memory module may be implemented as an Unbuffered Dual In-line Memory Module (UDIMM), a Registered DIMM (RDIMM), a Load Reduced DIMM (LRDIMM), a Fully Buffered DIMM (FBDIMM), a Small Outline DIMM (SODIMM), etc. For the purposes of discussion, example embodiments are described assuming that the memory device 10 is a stacked memory device in which a plurality of memory dies are vertically stacked, but it will be understood by those ordinarily skilled in the art that the present disclosure is likewise applicable to other types of memory devices, without departing from the spirit and scope of the present disclosure.

The host 20 may control an operation of the memory device 10. For example, the host 20 may test whether the memory device 10 is operating normally, as desired, and/or as designed. In order to test the memory device 10, the host 20 may control the operation of the memory device 10 by transmitting various signals to the memory device 10. The host 20 may determine whether the memory device corresponds to ‘pass’ or ‘fail’, based on the operation of the memory device 10.

The host 20 may transmit, for example, a clock CLK, a command CMD, an address ADDR and/or data DATA to the memory device 10. The host 20 may transmit the command CMD, the address ADDR and/or the data DATA to store the data DATA in the memory device 10 or read the data DATA stored in the memory device 10.

For example, the host 20 may write the data in desired (or, alternatively, a specific) address of the memory device 10 and read the data from the address in which the data is written. The host 20 may compare the written data with the read data to determine whether the memory device 10 corresponds to ‘fail’.

The memory device 10 may include a buffer die 110 and a plurality of core dies 120a and 120b. Although two core dies are shown in FIG. 1, the memory device 10 may include two or more core dies depending on application and/or design. The memory device 10 may be packaged by stacking the buffer die 110 and the plurality of core dies 120a and 120b, respectively. The core dies 120a and 120b stacked on the buffer die 110 are electrically connected to the buffer die 110. The buffer die 110 may be electrically connected to the core dies 120a and 120b using, for example, a through silicon via TSV included in the memory device 10. The buffer die 110 may perform communication with the host 20, and each of the core dies 120a and 120b may be a dynamic random access memory (DRAM) such as a Double Data Rate Synchronous Dynamic Random Access Memory (DDR SDRAM), a Low Power Double Data Rate (LPDDR) SDRAM, a Graphics Double Data Rate (GDDR) SDRAM, and a Rambus Dynamic Random Access Memory (RDRAM).

The first core die 120a may include a core control circuit 121a and the second core die 120b may include a core control circuit 121b, and the core control circuits 121a and 121b may receive a control command through the buffer die 110 to control each of the core dies 120a and 120b and/or a plurality of memory cells included in the core dies 120a and 120b. In other words, the first core die 120a may include a first core control circuit 121a, and the first core control circuit 121a may receive the control command through or from the buffer die 110 to control the first core die 120a and/or the plurality of memory cells included in the first core die 120a. In addition or alternatively, the second core die 120b may include a second core control circuit 121b, and the second core control circuit 121b may receive the control command through or from the buffer die 110 to control the second core die 120b and/or the plurality of memory cells included in the second core die 120b. For example, during a test operation for the memory device 10, the buffer die 110 may transfer signals received from the host 20 to the core dies 120a and 120b, and the core control circuits 121a and 121b of the core dies 120a and 120b may control internal circuits of the memory device 10 based on the signals transferred or received from the buffer die 110. Each of the core control circuits 121a and 121b may include a test mode register set (TMRS). The TMRS may store information that may be used for performing a test.

Each of the dies 110, 120a and 120b may operate in different operation states. Different standby currents may flow to each of the dies 110, 120a and 120b depending on the operation state. For example, when a test operation for a given core die (e.g., the first core die 120a) is being performed, an IDD2N current may flow to another core die (e.g., the second core die 120b) for which the test is not performed. The IDD2N may be based on the JEDEC standard, and may indicate a state in which a precharge standby current flows. In other words, another core die (e.g., the second core die 120b) for which the test is not being performed may receive power from the host 20, and the host 20 may supply power to the core die that is not being tested.

In addition or alternatively, the buffer die 110 may reset all of the plurality of core dies. When a reset command is output, all the core dies (e.g., the core dies 120a and 120b) on the buffer die 110 may be in a reset state. In the reset state, each of the plurality of core dies 120a and 120b may be in a state in which power of a memory cell array excluding a TSV area, which includes a TSV, and circuits related to an operation of inputting or outputting data to or from the memory cell array is at least partially reduced or limited.

The buffer die 110 may include a physical layer. The physical layer may include interface circuits for communication with an external host 20. The physical layer may include an interface circuit corresponding to each of a plurality of channels. Signals received from the outside (e.g., the host 20) through the physical layer may be transferred to the core dies 120a and 120b through TSVs.

The buffer die 110 may include a plurality of pins (or connections) for receiving signals from signal source(s) external to the buffer die 110. As described with reference to FIG. 1, the buffer die 110 may receive a clock signal CLK, a command signal CMD, an address signal CA and/or a data signal DATA through the plurality of pins, and may transmit the data signal DATA.

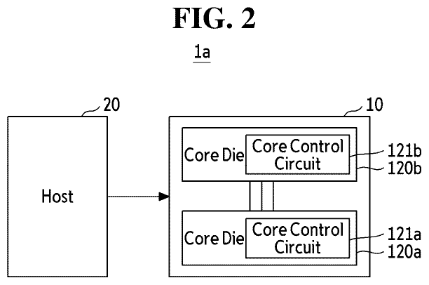

FIG. 2 is a block diagram of a memory system 1a according to some example embodiments. The memory system 1a may be same as or similar in some respects to the memory system 1 of FIG. 1, and therefore may be best understood with reference thereto where like numerals indicate like elements not described again in detail.

Referring to FIG. 2, a memory system 1a may include a memory device 10 and a host 20. A buffer die may be omitted in the memory system 1a and the memory device 10 of FIG. 2.

For example, each of the core dies 120a and 120b may include core control circuits 121a and 121b, and the core control circuits 121a and 121b may directly receive an external control command (e.g., from the host 20) to control each of the core dies 120a and 120b and the plurality of memory cells included in each of the core dies 120a and 120a and 120b. In some example embodiments, the first core die 120a may include a first core control circuit 121a, and the first core control circuit 121a may directly receive an external control command (e.g., from the host 20) to control the first core die 120a and/or the plurality of memory cells included in the first core die 120a. The second core die 120b may include a second core control circuit 121b, and the second core control circuit 121b may directly receive an external control command (e.g., form the host 20) to control the second core die 120b and/or the plurality of memory cells included in the second core die 120b.

The host 20 may reset all of the plurality of core dies. When the reset command is output from the host 20, all the core dies (e.g., the core dies 120a and 120b) of the memory device 10 may be in a reset state. In the reset state, each of the plurality of core dies 120a and 120b may be in a state in which power of a memory cell array excluding a TSV area, which includes a TSV, and circuits related to an operation of inputting or outputting data to or from the memory cell array is at least partially reduced or limited.

The first core die 120a may include a physical layer. The physical layer may include interface circuits for communication with the external host 20. The physical layer may include an interface circuit corresponding to each of a plurality of channels. Signals received externally (e.g., from the host 20) through the physical layer may be transferred to the second core die 120b through TSVs.

The first core die 120a may include a plurality of pins (or connectors) for receiving external signals. As described with reference to FIG. 1, the first core die 120a may receive the clock signal CLK, the command signal CMD, the address signal CA and/or the data signal DATA through the plurality of pins, and may transmit the data signal DATA.

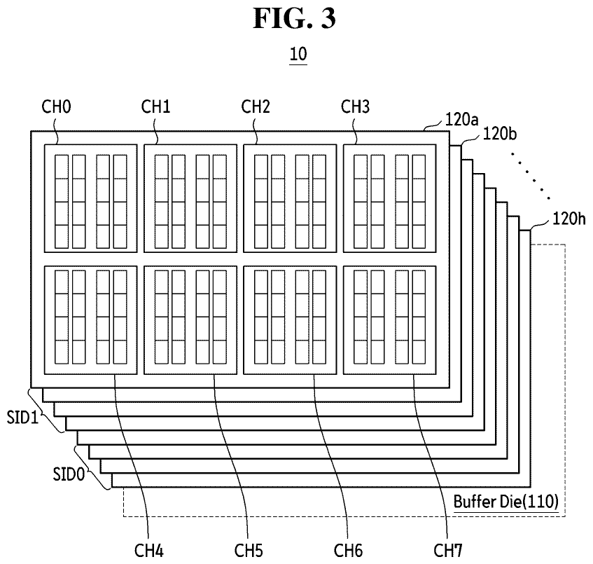

FIG. 3 is a view illustrating the memory device of FIGS. 1 and 2.

Referring to FIG. 3, the memory device 10 may include a buffer die 110 and a plurality of core dies 120a to 120h. For example, the buffer die 110 may be referred to as an interface die, a base die, a logic die, a master die, or the like, and each of the core dies 120a to 120h may be referred to as a memory die, a slave die, or the like. Although FIG. 3 shows that eight core dies 120a to 120h are included in the memory device 10, the number of core dies are not limited thereto. For example, the memory device 10 may include 8, 12, or 16 core dies, or may include more than 16 core dies. The buffer die 110 may not be included in the memory device 10, according to some example embodiments. However, for the sake of explanation, it is assumed that the memory device 10 includes the buffer die 110.

The buffer die 110 and the core dies 120a to 120h may be electrically connected through the through silicon via TSV. Accordingly, the memory device 10 may have a three-dimensional memory structure in which a plurality of dies are stacked. For example, the memory device 10 may be implemented based on a high bandwidth memory (HBM) or hybrid memory cube (HMC) standard. The memory device 10 may support a plurality of channels (or, referred to as vaults), which may be functionally independent. For example, as shown in FIG. 3, the first core die 120a may support eight channels CH0 to CH7. Likewise, the second core die 120b may also support eight channels. In some example embodiments, the first core die 120a and the second core die 120b may support their respective channels independent from each other. According to some example embodiments, at least some of the core dies may support the same (or common) channel. For example, when the memory device 10 includes eight core dies, one of four core dies constituting one stack and one of four core dies constituting the other stack may support the same channel. The core dies supporting the same channel may be classified by stack IDs (SID). For example, the first to fourth core dies supporting different channels may have stack ID of SID1, and the fifth to eighth core dies may have stack ID of SID0. In FIG. 3, since eight channels are supported per core die and four core dies have one stack ID, 32 channels may be supported per stack ID (SID).

Each of the channels may include an independent command and a data interface. For example, the respective channels may be independently clocked based on an independent timing requirement, and may not be synchronized with each other.

Each of the channels may include a plurality of memory banks. Each of the memory banks may include memory cells connected to word lines and bit lines, a sense amplifier, and the like.

The buffer die 110 may include a physical layer. The physical layer may include interface circuits for communication with the external host device. The physical layer may include an interface circuit corresponding to each of the plurality of channels. Signals received externally (e.g., from the host 20) through the physical layer may be transferred to the core dies 120a to 120h through the TSVs.

The buffer die 110 may include a plurality of pins for receiving external signals. As described with reference to FIG. 1, the buffer die 110 may receive the clock signal CLK, the command signal CMD, the address signal CA and/or the data signal DATA through the plurality of pins, and may transmit the data signal DATA.

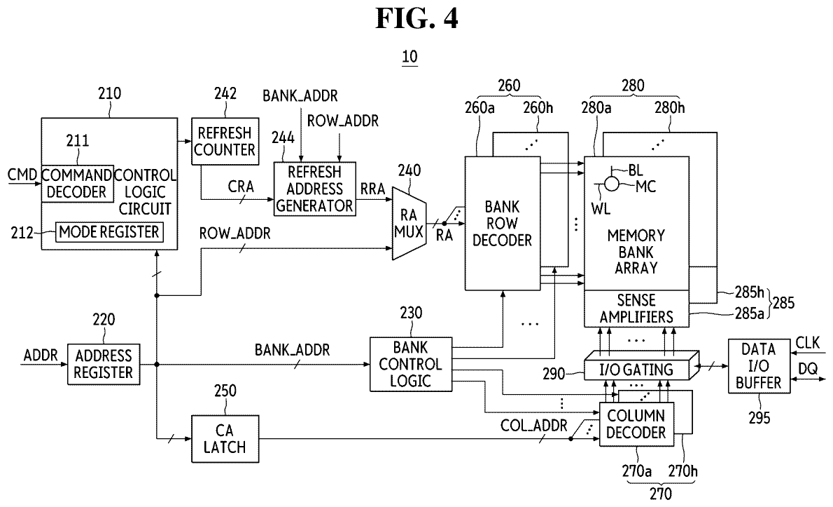

FIG. 4 is a block diagram illustrating a memory device of FIGS. 1 and 2, according to some example embodiments.

Referring to FIG. 4, the memory device 10 may include a control logic circuit 210, a voltage generator 213, an address register 220, a bank control logic circuit 230, a row address multiplexer 240, a refresh counter 242, a refresh address generator 244, a column address latch 250, a row decoder 260, a column decoder 270, a memory cell array 280, a sense amplifier 285, an input/output gating circuit 290, and/or a data input/output buffer 295.

The memory cell array 280 may include a plurality of memory bank arrays 280a to 280h. Although FIG. 4 shows that the memory cell array 280 include eight memory bank arrays 280a to 280h, example embodiments are not limited thereto.

Each of the plurality of memory bank arrays 280a to 280h may include a plurality of word lines WL, a plurality of bit lines BL, and a plurality of memory cells MC formed at a point where the word lines WL and the bit lines BL cross each other.

The row address multiplexer 240 may include a plurality of bank row decoders 260a to 260h connected to the plurality of memory bank arrays 280a to 280h, respectively. The column decoder 270 may include a plurality of column decoders 270a to 270h connected to a plurality of memory bank arrays 280a to 280h, respectively. The sense amplifier 285 may include a plurality of sense amplifiers 285a to 285h connected to the plurality of memory bank arrays 280a to 280h, respectively.

The address register 220 may receive an address ADDR, which includes a bank address BANK_ADDR, a row address ROW_ADDR and a column address COL_ADDR, externally. The address register 220 may provide the received bank address BANK_ADDR to the bank control logic circuit 230, provide the received row address ROW_ADDR to the row address multiplexer 240 and provide the received column address COL_ADDR to the column address latch 250.

The bank control logic circuit 230 may generate bank control signals in response to the bank address BANK_ADDR. In response to the bank control signals, the bank row decoder, which corresponds to the bank address BANK_ADDR, among the plurality of bank row decoders 260a to 260h may be activated, and the column decoder, which corresponds to the bank address BANK_ADDR, among the plurality of column decoders 270a to 270h may be activated.

The refresh counter 242 may sequentially output counting row addresses CRA under the control of the control logic circuit 210. For example, the control logic circuit 210 may generate a refresh count signal in response to a normal refresh command. The refresh counter 242 may perform a counting operation in response to the refresh count signal, and may output the counting row address CRA. In some example embodiments, the refresh counter 242 may output a refresh address for performing a normal refresh operation.

The refresh address generator 244 may receive the bank address BANK_ADDR and the row address ROW_ADDR. The refresh address generator 244 may count a value, at which the bank address BANK_ADDR and the row address ROW_ADDR are activated, based on the bank address BANK_ADDR and the row address ROW_ADDR. The refresh address generator 244 may generate a row address corresponding to a word line activated more than a predetermined number of times or a row address corresponding to an adjacent word line of the word line as a hammer address based on the counted value. In some example embodiments, the refresh address generator 244 may output a refresh address for performing a target row refresh operation.

The refresh address generator 244 may output any one of the counting row address CRA and the hammer address as a refresh row address RRA.

The refresh counter 242 and the refresh address generator 244 may be implemented as separate, distinct elements as shown, or the refresh counter 242 and the refresh address generator 244 may be implemented as a single element. Also, the refresh counter 242 and the refresh address generator 244 may be implemented to be included in the control logic circuit 210.

The row address multiplexer 240 may receive the row address ROW_ADDR from the address register 220, and may receive the refresh row address RRA from the refresh address generator 244. The row address multiplexer 240 may selectively output the row address ROW_ADDR or the refresh row address RRA as the row address RA. The row address RA output from the row address multiplexer 240 may be applied to each of the plurality of bank row decoders 260a to 260h.

A bank row decoder, which is activated by the bank control logic circuit 230, among the plurality of bank row decoders 260a to 260h may decode the row address RA output from the row address multiplexer 240 to activate a word line corresponding to the row address. For example, the activated bank row decoder may apply a word line driving voltage to the word line corresponding to the row address.

The column address latch 250 may receive the column address COL_ADDR from the address register 220, and may temporarily store the received column address COL_ADDR. The column address latch 250 may gradually increase the received column address COL_ADDR in a burst mode. The column address latch 250 may apply the temporarily stored column address COL_ADDR or the gradually increased column address COL_ADDR to each of the plurality of column decoders 270a to 270h.

A bank column decoder, which is activated by the bank control logic circuit 230, among the plurality of column decoders 270a to 270h may activate the sense amplifier corresponding to the bank address BANK_ADDR and the column address COL_ADDR through the corresponding input/output gating circuit 290.

The input/output gating circuit 290 may include an input data mask logic, read data latches for storing data output from the plurality of memory bank arrays 280a to 280h, and write drivers for writing data in the plurality of memory bank arrays 280a to 280h, along with circuits for gating input/output data.

The data DQ to be read from one bank array among the plurality of memory bank arrays 280a to 280h may be sensed by a sense amplifier (one of 285a to 285h) corresponding to the one bank array and stored in the read data latches. The data DQ stored in the read data latches may be provided to the outside through the data input/output buffer 295.

The data DQ to be written in one of the plurality of memory bank arrays 280a to 280h may be provided to the input/output gating circuit 290, and the input/output gating circuit 290 may write the data in the one bank array through the write drivers.

The control logic circuit 210 may control the operation of the memory device 10. For example, the control logic circuit 210 may generate control signals so that the memory device 10 performs a write operation or a read operation. The control logic circuit 210 may include a command decoder 211 for decoding the command CMD received from the host 20 and a mode register 212 for setting an operation mode of the memory device 10. The mode register 212 may include the TMRS described in FIG. 1.

For example, the command CMD may include an active command for converting the memory cell array 280 to an active state to write or read data, a precharge command for converting the memory cell array 280 to a standby state, a refresh command for controlling a refresh operation for the memory cell array 280, and a command for reading information stored in the mode register 212.

The control logic circuit 210, the voltage generator 213, the address register 220, the bank control logic circuit 230, the row address multiplexer 240, the refresh counter 242, the refresh address generator 244, the column address latch 250, the row decoder 260, the column decoder 270, the memory cell array 280, the sense amplifier 285, the input/output gating circuit 290, and/or the data input/output buffer 295 of FIG. 4 may be disposed in the buffer die 110 or the plurality of core dies 120a and 120b of FIG. 1 when the buffer die 110 is omitted. For example, the plurality of memory bank arrays 280a to 280h of the memory cell array 280 may be disposed or arranged in each of the core dies 120a and 120b.

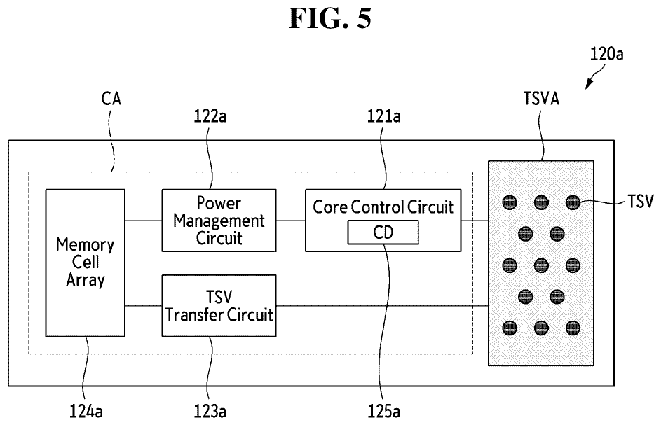

FIG. 5 is a block diagram illustrating the first core die 120a of the plurality of core dies, according to some example embodiments.

Referring to FIG. 5, the first core die 120a may include a cell area CA and a TSV area TSVA. TSVs configured to pass through the core dies may be disposed in the TSV area TSVA. The buffer die 110 may transmit and receive various signals to and from the first core die 120a through the TSVs. The first core die 120a may transmit and receive signals to and from the buffer die 110 and other core dies through the TSVs. A TSV power voltage for supplying power to the TSV may be used for signal transmission through the TSVs. When the power supplied to the TSV is reduced or limited, signal transmission through the TSV may be reduced or limited.

The cell area CA may include a core control circuit 121a, which includes a command decoder 125a, a power management circuit 122a, a TSV transfer circuit 123a, and a memory cell array 124a. According to some example embodiments, the core control circuit 121a may be one of the core control circuits 121a and 121b of FIGS. 1 and 2. The memory cell array 124a may be implemented as a portion of the memory cell array 280 of FIG. 4. The core control circuit 121a may receive various commands from the buffer die 110, and the command decoder 125a may decode the received commands. The core control circuit 121a may output a control signal for controlling the power management circuit 122a, the TSV transfer circuit 123a and the memory cell array 124a based on the commands decoded by the command decoder 125a. The power management circuit 122a may reduce or limit at least some power of the cell area CA in accordance with the control signal received from the core control circuit 121a. For example, the power management circuit 122a may reduce or limit power of at least a portion (e.g., at least a portion of the sense amplifier 285 of FIG. 3) of the TSV transfer circuit 123a of the cell area CA in accordance with the control signal received from the core control circuit 121a. A method of reducing or limiting power will be described later. The TSV transfer circuit 123a may input or output data to or from the memory cell array 124a through the TSV. Furthermore, the TSV transfer circuit 123a may buffer data input or output to or from the memory cell array 124a through the TSV. The TSV transfer circuit 123a may function or operate as a passage for writing or reading data in or from each memory cell array 124. For example, the TSV transfer circuit 123a may be implemented as a portion of the row decoder 260, the column decoder 270, the memory cell array 280, the sense amplifier 285, the input/output gating circuit 290 and/or the data input/output buffer 295 of FIG. 3.

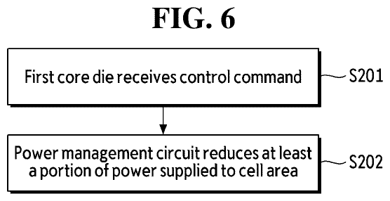

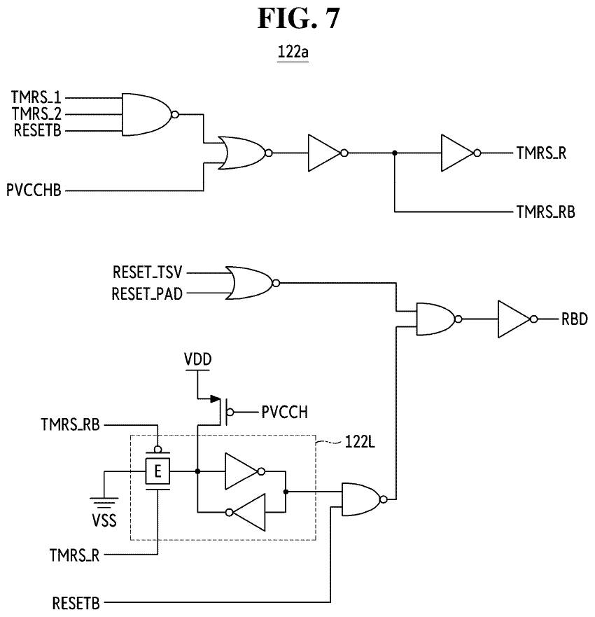

FIG. 6 is a flow chart illustrating a method for operating a memory device according to some example embodiments. FIG. 7 is a circuit diagram illustrating the power management circuit 122a of FIG. 5, according to some example embodiments.

In the circuit diagram of FIG. 7, some elements and signals may be omitted. Although some signals are described as having logic high ‘H’ or logic low ‘L’, a signal described as having logic high ‘H’ may have logic low ‘L’ on the contrary, or a signal described as having logic low ‘L’ may have logic high ‘H’. Referring to FIGS. 1 to 7, prior to operation S201, the memory device may start performing a test of the second core die 120b in accordance with a command of the host 20. For example, in accordance with the command of the host 20, the memory device 10 may write data in a desired (or, alternatively, a specific) address of the second core die 120b and read the written data from the address in which the written data is stored. However, according to some example embodiments, the test of the second core die 120b may not be performed prior to the operation S201, and this operation may be omitted.

The first core die 120a receives a control command from a test circuit of the buffer die 110 (operation S201). For example, the buffer die 110 may receive an externally provided operation command for the first core die 120a (e.g., from the host 20), the core control circuit 121a of the first core die 120a may receive the control command from the buffer die 110, and the command decoder 125a may decode the control command to output the control signal to the power management circuit 122a. However, according to some example embodiments, each core die may directly receive the control command that is externally provided thereto (e.g., from the host 20).

The power management circuit 122a receives the control signal from the command decoder 125a and reduces or limits at least some power supplied to the cell area CA of the first core die 120a based on the control signal (operation S202). When the core control circuit 121a receives a command to reduce or limit at least some power of the cell area CA of the first core die 120a, the command decoder 125a may output first and second TMRS signals TMRS_1 and TMRS_2 to the power management circuit 122a. When both the first and second TMRS signals TMRS_1 and TMRS_2 are logic high ‘H’ (or asserted), for example, in the power management circuit 122a, a power limiting signal RBD that reduces or limits at least some power of the cell area CA of the first core die 120a may be activated (e.g., the power limiting signal RBD outputs logic low ‘L’). Before the power limiting signal RBD is activated, a standby current used for buffering may flow to the first core die 120a. For example, the first core die 120a may be a state in which a precharge standby current (e.g., IDD2N) defined in the JEDEC standard flows in the first core die 120a. When the power limiting signal RBD is activated, at least some power supplied to the cell area CA of the first core die 120a may be reduced or limited. Circuits (e.g., the TSV transfer circuit 123a) used to input/output data may be included in the cell area CA of the first core die 120a. A state in which at least some power supplied to the circuits (e.g., the TSV transfer circuit 123a) used to input/output data to/from the first core die 120a is reduced may be the same as the reset state according to the reset command of the host 20 described above.

According to some example embodiments, the power management circuit 122a may further receive reset signals RESET_TSV and RESET_PAD, a power stabilization signal PVCCH and a power stabilization inversion signal PVCCHB. The buffer die 110 may generate the power stabilization signal PVCCH indicating that a level of a power voltage has reached a target voltage level. According to some example embodiments, the buffer die 110 may be omitted and the power stabilization signal PVCCH may be generated by the core control circuit 121a, but is not limited thereto. For example, the power stabilization signal PVCCH is initially logic low ‘L’, and then may be logic high ‘H’ when the power voltage is stabilized. In some example embodiments, the power stabilization signal PVCCH is initially logic high ‘H’, and then may be logic low ‘L’ when the power voltage is stabilized. The power stabilization inversion signal PVCCHB may be a signal obtained by inverting the power stabilization signal PVCCH. The power management circuit 122a may activate the power limiting signal RBD that limits or reduces at least some power of the cell area CA of the first core die 120a in accordance with the first and second TMRS signals TMRS_1 and TMRS_2 in a state that the power voltage is stabilized in accordance with the power stabilization signal PVCCH.

The buffer die 110 may also output reset signals RESET_TSV and RESET_PAD in accordance with the command from the host 20. When the buffer die 110 is omitted, according to some example embodiments, the host 20 may output the reset signals RESET_TSV and RESET_PAD to each core die. When the received reset signals RESET_TSV and RESET_PAD are, for example, logic high ‘H’, all the core dies including the first core die 120a and the core die, which is being tested, may be put into a reset state. In order to reduce or limit at least a portion of power only for the core dies that are not being tested, the buffer die 110 (or the host 20) may set the first and second reset signals RESET_TSV and RESET_PAD to logic low ‘L’. The first reset signal RESET_TSV may be, for example, a signal for resetting the core dies after stacking them, and the second reset signal RESET_PAD may be, for example, a signal for resetting the core dies before stacking them. In some example embodiments, the second reset signal RESET_PAD may be in a state of logic low ‘L’ (or non-asserted state) continuously after the core dies are stacked. For example, when both the first and second TMRS signals TMRS_1 and TMRS_2 are logic high ‘H’ and a third reset signal RESETB obtained by inverting the first reset signal RESET_TSV is logic high ‘H’, the power management circuit 122a may activate the power limiting signal RBD that reduces at least some power of the cell area CA of the first core die 120a.

According to some example embodiments, the power management circuit 122a may include a latch circuit 122L. The latch circuit 122L may include a latch capable of storing a third TMRS signal TMRS_R generated by the first and second TMRS signals TMRS_1 and TMRS_2 even when at least some power supplied to the cell area of the first core die 120a is reduced, and a transfer gate E for receiving the third TMRS signal TMRS_R and a fourth TMRS signal TMRS_RB obtained by inverting the third TMRS signal TMRS_R in both gates. An input of the transfer gate E is connected to a power ground terminal VSS, so that an output of the latch circuit 122L may be maintained at logic high ‘H’ when the third TMRS signal TMRS_R is logic high ‘H’, and the latch may store the third TMRS signal TMRS_R when the third TMRS signal TMRS_R is changed to logic low ‘L’. Afterwards, when the buffer die 110 outputs the reset signals RESET_TSV and RESET_PAD in accordance with the command of the host 20, the signal stored in the latch may be initialized by a transistor that receives the power stabilization signal PVCCH as an input of the gate.

According to some example embodiments, the power limiting signal RBD reduces or limits at least some power of the cell area CA of the first core die 120a, but may not reduce or limit power of the TSV area TSVA of the first core die 120a. As described above, when the power supplied to the TSV is reduced or limited, signal transmission through the TSV may be limited. Therefore, the power limiting signal RBD may not reduce or limit the power of the TSV area TSVA of the first core die 120a.

In the core dies where at least some power supplied to the cell area is reduced, power may be restored in some situations. For example, power may be restored after the testing of the core die has concluded. According to some example embodiments, the buffer die 110 may receive an operation command for the first core die 120a from an external source (e.g., the host 20) in a state that at least some power supplied to the cell area of the first core die 120a is reduced, and may output a reset command for initializing all of the plurality of core dies 120a to 120h. The plurality of core dies 120a to 120h that have received the reset command may be restored to a state before at least some power supplied to the cell area is reduced after the reset is completed. For example, the signal stored in the latch may be initialized by the transistor that receives the power stabilization signal PVCCH as the input of the gate, so that the power in the cell area CA that was reduced previously may be restored.

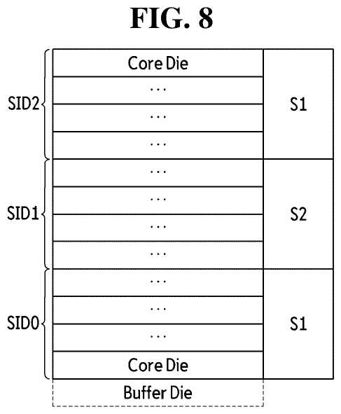

FIG. 8 illustrates a plurality of core dies including a first stack ID of SID0, a second stack ID of SID1, and a third stack ID of SID2, according to some example embodiments.

The method of operating the memory device, according to some example embodiments, is discussed with reference to FIG. 8. Referring to FIG. 8, when a test is performed for the plurality of core dies having a second stack ID of SID1 in accordance with the command of the host, the plurality of core dies having a first stack ID of SID0 and a third stack ID of SID2 may be in a standby state. The standby state may be, for example, a state in which a precharge standby current IDD2N flows, and the host may supply power to one or more core dies that are not currently being tested.

According to some example embodiments, the buffer die may provide the plurality of core dies having a first stack ID of SID0 and a third stack ID of SID2 with a command to reduce or limit at least some power supplied to the cell area, and each command decoder of the plurality of core dies having a first stack ID of SID0 and a third stack ID of SID2 may receive the command and output a signal to reduce or limit at least some power of the cell area.

According to some example embodiments, the host may reduce or limit at least some power supplied to the one or more core dies that are not currently being tested, so that the cost required for the test may be reduced, and more memory devices may be tested, whereby the time required for the test may be reduced.

When the reset command is output by the buffer die, all the core dies on the buffer die may be in a reset state. Therefore, when the reset command is output when a core die is being tested, the test may be interrupted or stopped. According to some example embodiments, the buffer die may change only the core die selected among all the core dies to the same state S1, e.g., a reset state according to the reset command by outputting the control command even without outputting the reset signal. The core die that is not selected may be in a different state S2 from that of the selected core die. The different state may include, for example, a state in which the test is being performed, or a standby state. When the selected core die is changed to the same state as the reset state according to the reset command, the power consumed by the selected core die may be smaller than a state in which the standby precharge current IDD2N defined in the JEDEC standard flows to the corresponding core die, and may be smaller than a state in which a standby power down current IDD2P defined in the JEDEC standard flows. Therefore, the power consumed by the core die selected by the host may be reduced by a relatively higher amount compared to when testing is performed, or in a standby state.

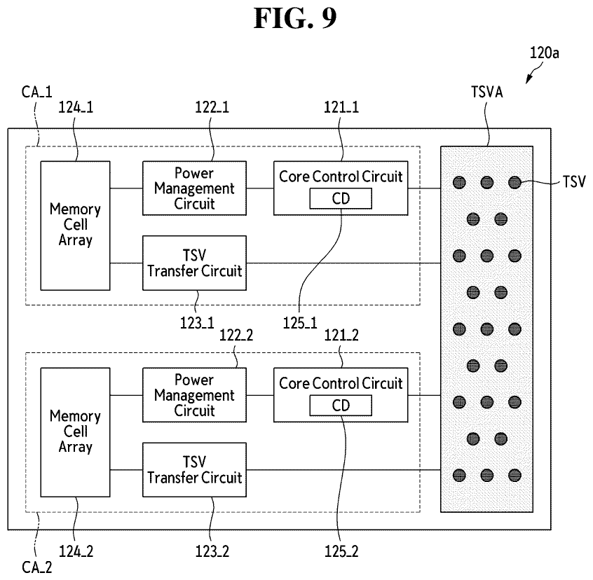

FIG. 9 is a block diagram illustrating the first core die 120a of FIGS. 1 and 2, according to some example embodiments.

Referring to FIG. 9, the first core die 120a may support at least two channels. The first core die 120a may include a first cell area CA_1 corresponding to a first channel, a second cell area CA_1 corresponding to a second channel, and a TSV area TSVA. In some example embodiments, the first channel and the second channel may operate independently of each other and the first core die 120a may include separate TSV areas for each of the first channel and the second channel. The signals may be independently transmitted and received through TSVs corresponding to each channel. For example, when a data signal is transmitted to the first channel to store data in the first memory cell array 124_1 of the first channel, the buffer die may transmit the data signal to the first cell area CA_1 of the first core die 120a through the TSVs corresponding to the first channel. Therefore, data may be stored in the first memory cell array 124_1 of the first channel.

TSVs configured to pass through the core dies may be disposed in the TSV area TSVA. The buffer die 110 may transmit and receive various signals to and from the first and second channels of the first core die 120a through the TSVs. A TSV power voltage for supplying power to the TSV may be used for signal transmission through the TSVs. When the power supplied to the TSV is reduced, signal transmission through the TSV may not be possible.

The first cell area CA_1 may include a first channel control circuit 121_1, a first command decoder 125_1, a first power management circuit 122_1, a first TSV transfer circuit 123_1, and a first memory cell array 124_1. The second cell area CA_2 may include a second channel control circuit 121_2, a second command decoder 125_2, a second TSV transfer circuit 123_2, and a second memory cell array 124_2. Each of the channel control circuits 121_1 and 121_2 may receive various commands from the buffer die 110 (or the host 20) and decode them using the command decoders 125_1 and 125_2 to output control signals for controlling each of the power management circuits 122_1 and 122_2, each of the TSV transfer circuits 123_1 and 123_2 and each of the memory cell arrays 124_1 and 124_2. Each of the power management circuits 122_1 and 122_2 may reduce or limit at least some power supplied to the first or second cell area CA_1 or CA_2 in response to the control signal received from each of the command decoders 125_1 and 125_2. Each of the memory cell arrays 124_1 and 124_2 may include at least a portion of the plurality of memory bank arrays 280a to 280h of FIG. 3. Each of the TSV transfer circuits 123_1 and 123_2 may input or output data to or from each of the memory cell arrays 124_1 and 124_2 through the TSV. Also, each of the TSV transfer circuits 123_1 and 123_2 may buffer data to be input or output to or from each of the memory cell arrays 124_1 and 124_2 through the TSV. Each of the TSV transfer circuits 123_1 and 123_2 may function as a passage or medium for writing or reading data in or from each of the memory cell arrays 124_1 and 124_2.

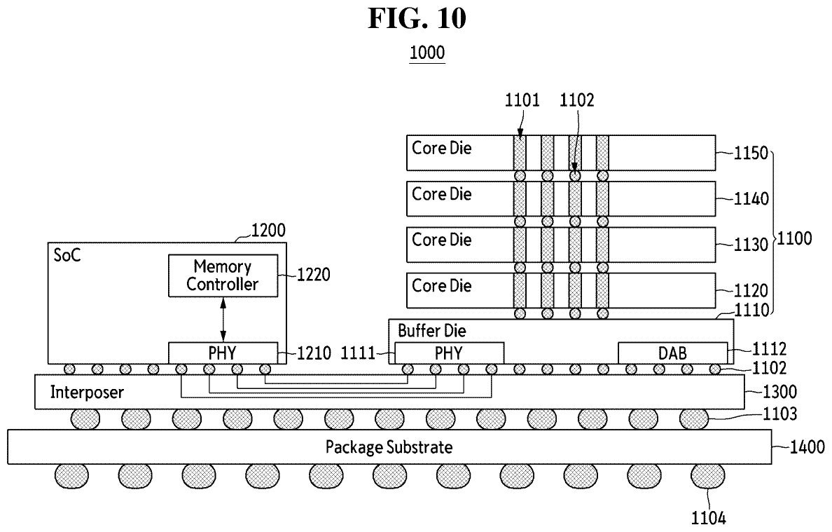

FIG. 10 is a view illustrating a semiconductor package including the memory device of FIGS. 1 and 2, according to some example embodiments.

Referring to FIG. 10, a semiconductor package 1000 may include a stacked memory device 1100, a system-on-chip 1200, an interposer 1300, and a package substrate 1400. The stacked memory device 1100 may include a buffer die 1110 and core dies 1120 to 1150. The core dies 1120 to 1150 may include the memory device 10 described with reference to FIGS. 1 to 8. The buffer die 1110 may include a physical layer 1111 and a direct access area (DAB) 1112. The physical layer 1111 may be electrically connected to a physical layer 1210 of the system-on-chip 1200 through the interposer 1300. The stacked memory device 1100 may receive signals from the system-on-chip 1200 through the physical layer 1111, or may transmit the signals to the system-on-chip 1200. According to some example embodiments, the buffer die 1110 may be omitted, and the interposer 1300 may be directly connected to the core dies 1120 to 1150.

The direct access area 1112 may provide an access path that may test the stacked memory device 1100 without passing through the system-on-chip 1200. The direct access area 1112 may include electrical connections (e.g., port or pin) that may directly communicate with an external test device. A test signal and data received through the direct access area 1112 may be transmitted to the core dies 1120 to 1150 through TSVs. Data read from the core dies 1120 to 1150 to test the core dies 1120 to 1150 may be transmitted to the test device through the TSVs and the direct access area 1112. Therefore, a direct access test for the core dies 1120 to 1150 may be performed.

The buffer die 1110 may be electrically connected to the core dies 1120 to 1150 through TSVs 1101 and bumps 1102. The buffer die 1110 may receive signals provided to each channel through the bumps 1102 allocated for each channel from the system-on-chip 1200. For example, the bumps 1102 may be micro-bumps.

The system-on-chip 1200 may execute applications supported by the semiconductor package 1000 by using the stacked memory device 1100. For example, the system-on-chip 1200 may include at least one processor of a central processing unit (CPU), an application processor (AP), a graphic processing unit (GPU), a neural processing unit (NPU), a tensor processing unit (TPU), a vision processing unit (VPU), an image signal processor (ISP), or a digital signal processor (DSP) to execute specialized computations.

The system-on-chip 1200 may include the physical layer 1210 and a memory controller 1220. The physical layer 1210 may include input/output circuits for transmitting and receiving signals to and from the physical layer 1111 of the stacked memory device 1100. The system-on-chip 1200 may provide various signals to the physical layer 1111 through the physical layer 1210. The signals provided to the physical layer 1111 may be transferred to the core dies 1120 to 1150 through the TSVs 1101 and interface circuits of the physical layer 1111.

The memory controller 1220 may control the overall operation of the stacked memory device 1100. The memory controller 1220 may transmit signals for controlling the stacked memory device 1100 to the stacked memory device 1100 through the physical layer 1210. The memory controller 1220 may correspond to the host 20 of FIG. 1, in some example embodiments.

The interposer 1300 may connect the stacked memory device 1100 with the system-on-chip 1200. The interposer 1300 may connect the physical layer 1111 of the stacked memory device 1100 with the physical layer 1210 of the system-on-chip 1200, and may provide physical paths formed using conductive materials. Therefore, the stacked memory device 1100 and the system-on-chip 1200 may be stacked on the interposer 1300 to transmit and receive signals to and from each other.

Bumps 1103 may be attached to an upper portion of the package substrate 1400, and solder balls 1104 may be attached to a lower portion of the package substrate 1400. For example, the bumps 1103 may be flip-chip bumps. The interposer 1300 may be stacked on the package substrate 1400 through the bumps 1103. The semiconductor package 1000 may transmit and receive signals to and from other external packages or semiconductor devices through the solder balls 1104. For example, the package substrate 1400 may be a printed circuit board (PCB).

According to some example embodiments, the stacked memory device 1100 may correspond to the memory device 10 described with reference to FIGS. 1 to 8. Before the stacked memory device 1100 is packaged on the interposer 1300, a test for the core dies 1120 to 1150 may be performed. During a test operation for one (for example, the first core die 1120) of the plurality of core dies 1120 to 1150, the first core die 1120 and other core dies (for example, the core dies 1130 to 1150) may be controlled, operated, or configured to reduce or limit at least some power supplied to the cell area of the corresponding core die in accordance with an external command (for example, a command from the memory controller 1220, or the host 20 of FIG. 1). As a result, the power consumed when a single stacked memory device 1100 is tested may be reduced.

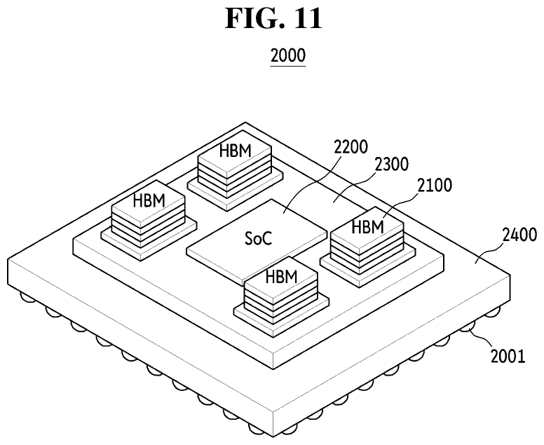

FIG. 11 illustrates a perspective view of an example semiconductor package including the memory device of FIG. 10.

Referring to FIG. 11, a semiconductor package 2000 may include a plurality of stacked memory devices 2100 and a system-on-chip 2200. The stacked memory devices 2100 and the system-on-chip 2200 may be stacked on the interposer 2300, and the interposer 2300 may be stacked on a package substrate 2400. The semiconductor package 2000 may transmit and receive signals to and from other external packages or semiconductor devices through solder balls 2001 attached to a lower portion of the package substrate 2400.

Each of the stacked memory devices 2100 may be implemented based on the HBM standard, but example embodiments are not limited thereto. Each of the stacked memory devices 2100 may be implemented based on the GDDR, HMC, or Wide I/O standard. According to some example embodiments, each of the stacked memory devices 2100 may correspond to the stacked memory device 1100 of FIG. 9.

The system-on-chip 2200 may include at least one processor such as a CPU, an AP, a GPU and an NPU, and a plurality of memory controllers for controlling the plurality of stacked memory devices 2100. The system-on-chip 2200 may transmit and receive signals to and from a corresponding stacked memory device through the memory controller. The system-on-chip 2200 may correspond to the system-on-chip 1200 of FIG. 9.

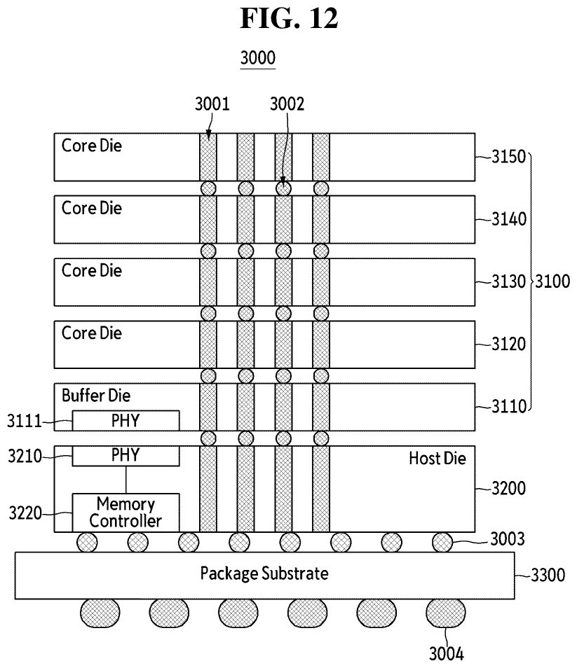

FIG. 12 illustrates a semiconductor package 3000 including the memory device 10 of FIG. 1, according to some example embodiments.

Referring to FIG. 12, the semiconductor package 3000 may include a stacked memory device 3100, a host die 3200, and a package substrate 3300. The stacked memory device 3100 may include a buffer die 3110 and core dies 3120 to 3150. The buffer die 3110 may include a physical layer 3111 for performing communication with the host die 3200, and each of the core dies 3120 to 3150 may include a memory cell array.

The host die 3200 may include a physical layer 3210 for performing communication with the stacked memory device 3100, and a memory controller 3220 for controlling the overall operation of the stacked memory device 3100. The host die 3200 may also include a processor for controlling the overall operation of the semiconductor package 3000 and executing an application supported by the semiconductor package 3000. For example, the host die 3200 may include at least one processor such as a CPU, an AP, a GPU and an NPU.

The stacked memory device 3100 may be disposed on the host die 3200 based on TSVs 3001 and vertically stacked on the host die 3200. Therefore, the buffer die 3110, the core dies 3120 to 3150 and the host die 3200 may be electrically connected to one another through the TSVs 3001 and bumps 3002 without an interposer. For example, the bumps 3002 may be micro-bumps.

Bumps 3003 may be attached to an upper portion of the package substrate 3300, and solder balls 3004 may be attached to a lower portion of the package substrate 3300. For example, the bumps 3003 may be flip-chip bumps. The host die 3200 may be stacked on the package substrate 3300 through the bumps 3003. The semiconductor package 3000 may transmit and receive signals to and from other external packages or semiconductor devices through the solder balls 3004.

According to some example embodiments, the stacked memory device 3100 may correspond to the memory device 10 described in FIGS. 1 to 8. Before the stacked memory device 3100 is packaged on the package substrate 3300, a test for the core dies 3120 to 3150 may be performed. During a test operation for one (for example, the first core die 3120) of the plurality of core dies 3120 to 3150, the first core die 3120 and other core dies (for example, the core dies 3130 to 3150) may be controlled, operated, or configured to reduce or limit at least some power supplied to the cell area of the corresponding core die in accordance with an external command (for example, the host 20 of FIG. 1). As a result, the power consumed when a single stacked memory device 3100 is tested may be reduced.

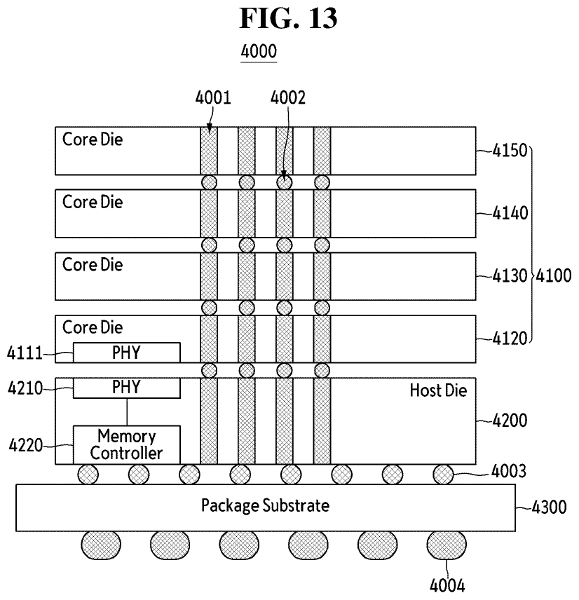

FIG. 13 illustrates a semiconductor package 4000 including the memory device of FIG. 2, according to some example embodiments. The semiconductor package 4000 may be same as or similar in some respects to the semiconductor package 3000 of FIG. 12 and may be best understood with reference thereto.

Referring to FIG. 13, the semiconductor package 4000 may include a stacked memory device 4100, a host die 4200, and a package substrate 4300. The stacked memory device 4100 may not include a buffer die. The core die 4120 includes a physical layer 4111 for performing communication with the host die 4200, and each of the core dies 4120 to 4150 may include a memory cell array.

As described herein, any devices, systems, modules, portions, units, controllers, circuits, and/or portions thereof according to any of the example embodiments, and/or any portions thereof (including, without limitation, the memory device 10, the host 20, buffer die 110, core dies 120a and 120b, core control circuits 121a and 121b, the control logic circuit 210, the voltage generator 213, the address register 220, the bank control logic circuit 230, the row address multiplexer 240, the refresh counter 242, the refresh address generator 244, the column address latch 250, the row decoder 260, the column decoder 270, the memory cell array 280, the sense amplifier 285, the input/output gating circuit 290, the data input/output buffer 295, SoC 1200, the memory controller 1220, the physical layer 1210, the interposers 1300 and 2300, the stacked memory devices 2100, the system-on-chip 2200, physical layers 3111, 3210, 4111, 4210, the memory controller 3220, 4220, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device comprising:
a plurality of core dies including a first core die, the first core die including:
a first through silicon via (TSV) area including a plurality of TSVs passing through the first core die; and
a first cell area including:
a first memory cell array configured to store received data;
a TSV transfer circuit configured to input and output data to and from the first memory cell array;
a first power management circuit configured to manage power of the first core die, the first power management circuit including a latch circuit; and
a core control circuit configured to control the first core die in accordance with at least one control command,
wherein the first power management circuit is configured to:
receive, from the core control circuit, a first control signal associated with reducing at least a portion of power supplied to the first cell area; and
reduce at least a portion of the power supplied to the first cell area based on the first control signal, and
wherein the latch circuit of the first power management circuit is configured to maintain a state of the first control signal such that the power of the first cell area is at least partially reduced.

2. The memory device of claim 1, wherein the plurality of core dies further includes a second core die different from the first core die, and
the first power management circuit is configured to reduce at least a portion of the power supplied to the first cell area in accordance with the first control signal based on the second core die being under a test operation.

3. The memory device of claim 1, wherein the core control circuit is configured to provide the first power management circuit with the first control signal by receiving a first control command among the at least one control command, the first control command being associated with reducing at least a portion of power of one or more core dies of the plurality of core dies.

4. The memory device of claim 1, wherein the core control circuit includes a command decoder configured to provide the first power management circuit with the first control signal associated with reducing at least a portion of the power supplied to the first cell area in accordance with the at least one control command.

5. The memory device of claim 1, wherein the latch circuit includes a latch configured to maintain the first control signal such that the power of the first cell area is at least partially reduced, and a transmission gate configured to provide the latch with a power ground voltage in accordance with the first control signal.

6. The memory device of claim 1, wherein the first power management circuit is further configured to:
receive a second control signal associated with initialization of each of the plurality of core dies of the memory device, and
restore the reduced power of the first cell area in accordance with the second control signal, the first cell area being in a state that the power supplied to the first cell area is at least partially reduced.

7. The memory device of claim 1, wherein the first core die includes a first channel and a second channel, the first channel and the second channel operating independently of each other, and the second channel being different from the first channel,
the first channel of the first core die includes a second cell area and a second TSV area including a plurality of TSVs, the second cell area further including a second memory cell array configured to store received data, a second TSV transfer circuit configured to input and output data to and from the second memory cell array, a second power management circuit configured to manage power of the first channel, and a channel control circuit configured to control the first channel in accordance with the at least one control command, and
the second power management circuit is configured to receive, from the channel control circuit, a second control signal to reduce at least a portion of power supplied to the first channel of the first and second channels, and reduce at least a portion of power supplied to the second cell area in accordance with the second control signal.

8. The memory device of claim 1, wherein the first power management circuit is configured to reduce at least a portion of the power supplied to the first cell area in accordance with the first control signal, and maintain power supplied to the first TSV area.

9. A memory device comprising:
a plurality of core dies including a first core die, the first core die including:
a first through silicon via (TSV) area having a plurality of TSVs passing through the first core die; and
a first cell area including:
a first memory cell array configured to store received data;
a first TSV transfer circuit configured to input and output data to and from the first memory cell array;
a first power management circuit configured to manage power of the first core die, the first power management circuit including a latch circuit; and
a core control circuit configured to control the first core die in accordance with at least one control command including a first control command associated with reducing at least a portion of power of one or more core dies among the plurality of core dies,
wherein the core control circuit is configured to:
receive the first control command associated with reducing the at least the portion of the power of the one or more core dies among the plurality of core dies; and
provide, to the first power management circuit, a first control signal associated with reducing the at least the portion of power supplied to the first cell area, in response to receiving the first control command, and
wherein the first power management circuit is configured to:
receive the first control signal from the core control circuit; and
reduce at least a portion of the power supplied to the first cell area in accordance with the first control signal.

10. The memory device of claim 9, wherein the plurality of core dies further includes a second core die different from the first core die, and
the first power management circuit is configured to reduce at least a portion of the power supplied to the first cell area in accordance with the first control signal based on the second core die being under a test operation.

11. The memory device of claim 9, wherein the core control circuit further includes a command decoder configured to provide the first power management circuit with the first control signal associated with reducing at least a portion of the power supplied to the first cell area in accordance with the first control command.

12. The memory device of claim 9, wherein the latch circuit is configured to maintain the first control signal in a state that the power of the first cell area is at least partially reduced.

13. The memory device of claim 12, wherein the latch circuit includes a latch configured to maintain a received signal in a state that at least a portion of power of the first cell area is reduced, and a transmission gate configured to provide the latch with a power ground voltage in accordance with the first control signal.

14. The memory device of claim 9, wherein the first power management circuit is further configured to receive a second control signal associated with initialization of each core die of the plurality of core dies of the memory device, and restore the reduced power of the first cell area in accordance with the second control signal, the first cell area being in a state that the power supplied to the first cell area is at least partially reduced.

15. The memory device of claim 9, wherein the first core die includes a first channel and a second channel, the first channel and the second channel operating independently of each other, and the second channel being different from the first channel,
the first channel of the first core die includes a second cell area and a second TSV area including a plurality of TSVs, the second cell area further including a second memory cell array configured to store received data, a second TSV transfer circuit configured to input and output data to and from the second memory cell array, a second power management circuit configured to manage power of the first channel, and a channel control circuit configured to control the first channel in accordance with the at least one control command, and
the second power management circuit is configured to,
receive, from the channel control circuit, a second control signal to reduce at least a portion of power supplied to the first channel of the first and second channels, and
reduce at least a portion of power supplied to the second cell area in accordance with the second control signal.

16. The memory device of claim 9, wherein the first power management circuit is configured to reduce at least a portion of the power supplied to the first cell area in accordance with the first control signal, and maintain power supplied to the first TSV area.

17. A method for operating a memory device comprising a plurality of core dies, the method comprising:
receiving, by a power management circuit of a first core die of the plurality of core dies, a first control signal associated with reducing at least a portion of power supplied to the first core die;
reducing, by the power management circuit of, at least a portion of the power supplied to a cell area of the first core die based on the first control signal; and
maintaining, by the power management circuit, the first control signal in a state that the power of the cell area is at least partially reduced.

18. The method of claim 17, wherein the reducing the at least the portion of the power supplied to the cell area by the power management circuit includes reducing at least a portion of power supplied to a through silicon via (TSV) transfer circuit of the first core die by the power management circuit.

19. The method of claim 17, further comprising:
receiving, by the first core die, a first control command associated with reducing at least a portion of the power supplied to the first core die; and
providing, by a core control circuit of the first core die, to the power management circuit with the first control signal.

20. The method of claim 19, further comprising:
receiving, by the first core die, a second control command to initialize each of the plurality of core dies of the memory device, the plurality of core dies being in a state that the power supplied to the cell area is at least partially reduced;
providing, by the core control circuit, to the power management circuit a second control signal to restore the reduced power of the cell area; and
restoring, by the power management circuit, the reduced power of the cell area in accordance with the second control signal.
